(19) United States
(12) Patent Application Publication
(10) Pub. No.: US 2025/0393291 A1
(43) Pub. Date: Dec. 25, 2025

(54) SEMICONDUCTOR DEVICE

(71) Applicant: FUJI ELECTRIC CO., LTD., Kanagawa (JP)

(72) Inventors: Taichi ITOH, Matsumoto-city (JP); Akio YAMANO, Frankfurt (DE)

(21) Appl. No.: 19/308,291

(22) Filed: Aug. 24, 2025

Related U.S. Application Data
(63) Continuation of application No. PCT/JP2024/027859, filed on Aug. 5, 2024.

(30) Foreign Application Priority Data
Sep. 14, 2023 (JP) 2023-149403
Feb. 26, 2024 (JP) 2024-026964

(51) Int. Cl. H10D 80/20; H01L 23/00; H01L 23/373; H01L 25/07; H01L 25/18

(52) U.S. Cl. CPC H10D 80/20; H01L 23/3735; H01L 24/48; H01L 25/072; H01L 25/18; H01L 2224/48137; H01L 2224/48225; H01L 2924/1203; H01L 2924/13055

(57) ABSTRACT

Provided is a semiconductor device including an upper arm circuit and a lower arm circuit and having a positive electrode terminal, a negative electrode terminal, and an output terminal, which includes an insulating plate; a first wiring pattern provided on the insulating plate; and a second wiring pattern provided on the insulating plate and spaced apart from the first wiring pattern, the upper arm circuit has a circuit in which the positive electrode terminal, a first diode portion provided on the first wiring pattern, a first transistor portion connected in series with the first diode portion and provided on the first wiring pattern, and the output terminal are connected and arranged in this order, and the lower arm circuit has a second transistor portion provided on the second wiring pattern, and a second diode portion provided on the second wiring pattern.

The contents of the following patent application(s) are incorporated herein by reference:
NO. 2023-149403 filed in JP on Sep. 14, 2023
NO. 2024-026964 filed in JP on Feb. 26, 2024
NO. PCT/JP2024/027859 filed in WO on Aug. 5, 2024.

### BACKGROUND

### 1. Technical Field

The present invention relates to a semiconductor device.

### 2. Related Art

Patent Document 1 describes a “semiconductor switch module for power, which can be adopted to various power conversion devices such as a current-fed inverter and a matrix converter by a single circuit configuration to enhance versatility and economic efficiency”.

### RELATED ART DOCUMENTS

### Patent Documents

Patent Document 1: Japanese Patent Application Publication No. 2006-187143
Patent Document 2: Japanese Patent Application Publication No. 2005-269735
Patent Document 3: Japanese Patent Application Publication No. 2003-164140
Patent Document 4: Japanese Patent Application Publication No. H7-25552
Patent Document 5: Japanese Patent Application Publication No. 2008-186920
Patent Document 6: Japanese Patent Application Publication No. 2014-155287

### BRIEF DESCRIPTION OF THE DRAWINGS

FIG. 1 shows an example of a perspective view of a semiconductor device 100.

FIG. 2A shows an example of a plan view of the semiconductor device 100.

FIG. 2B shows an example of an insulating plate 20 of the semiconductor device 100.

FIG. 3 shows an example of a configuration of a three-phase power conversion circuit.

FIG. 4A shows an example of a configuration of a three-phase power conversion circuit according to a comparative example.

FIG. 4B shows an example of a plan view of a semiconductor device 500 according to the comparative example.

FIG. 5A shows an insulating plate 20 of a variation of the semiconductor device 100.

FIG. 5B shows a circuit configuration of the variation of the semiconductor device 100.

FIG. 5C shows an insulating plate 20 of a variation of the semiconductor device 100.

FIG. 5D shows a circuit configuration of the variation of the semiconductor device 100.

FIG. 6A shows an insulating plate 20 of a variation of the semiconductor device 100.

FIG. 6B shows an insulating plate 20 of a variation of the semiconductor device 100.

FIG. 7 shows a perspective view of a variation of the semiconductor device 100.

FIG. 8A shows a plan view of a variation of the semiconductor device 100.

FIG. 8B shows a circuit configuration of the variation of the semiconductor device 100.

FIG. 9 shows a plan view of a semiconductor device 500 according to a comparative example.

FIG. 10A shows a plan view of a variation of the semiconductor device 100.

FIG. 10B shows an insulating plate 20 of a variation of the semiconductor device 100.

FIG. 11 shows a variation of the configuration of the three-phase power conversion circuit.

FIG. 12 shows an insulating plate 20 of a variation of the semiconductor device 100.

FIG. 13A shows an insulating plate 20 of a variation of the semiconductor device 100.

FIG. 13B shows a circuit configuration of the variation of the semiconductor device 100.

FIG. 13C shows an insulating plate 20 of a variation of the semiconductor device 100.

FIG. 13D shows a circuit configuration of the variation of the semiconductor device 100.

FIG. 14A shows an insulating plate 20 of a variation of the semiconductor device 100.

FIG. 14B shows an insulating plate 20 of a variation of the semiconductor device 100.

### DESCRIPTION OF EXEMPLARY EMBODIMENTS

Hereinafter, the present invention will be described through embodiments of the invention, but the following embodiments do not limit the invention according to claims. Also, not all of the combinations of features described in the embodiments are essential to the solving means of the invention.

In the present specification, one side in a direction parallel to a depth direction of a semiconductor substrate included in a semiconductor chip is referred to as an “upper” side, and another side is referred to as a “lower” side. One surface of two principal surfaces of a substrate, a layer or other member is referred to as an upper surface, and the other surface is referred to as a lower surface. “Upper”, “lower”, “front”, and “back” directions are not limited to a direction of gravity, or a direction of attachment to a substrate or the like when a semiconductor device is implemented.

In the present specification, technical matters may be described by using orthogonal coordinate axes of an X axis, a Y axis, and a Z axis. In the present specification, a plane parallel to an upper surface of the semiconductor chip is referred to as an XY plane, and the depth direction of the semiconductor substrate included in the semiconductor chip is referred to as the Z axis.

In the present specification, a case where a term such as “same” or “equal” is mentioned may include a case where an error due to a variation in manufacturing or the like is included. The error is, for example, within 10%.

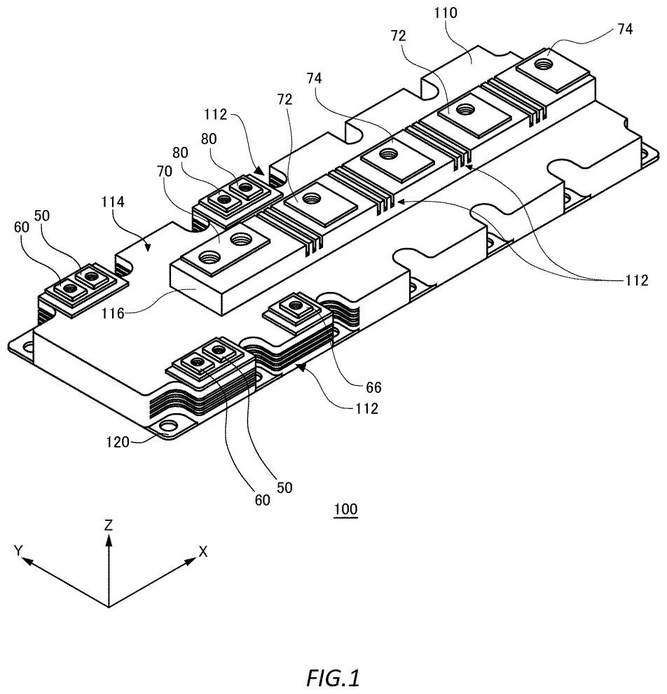

FIG. 1 shows an example of a perspective view of a semiconductor device 100. The semiconductor device 100 includes a casing portion 110, a base portion 120, and a plurality of terminals. The semiconductor device 100 may function as part of a power conversion device such as an inverter or a converter. The semiconductor device 100 may house a semiconductor chip and the like inside.

The casing portion 110 houses the semiconductor chip and the like included in the semiconductor device 100. The casing portion 110 is molded of resin with insulation properties. The casing portion 110 is provided on the base portion 120. The casing portion 110 may be provided with a cutout 112 for ensuring insulation properties.

The base portion 120 is fixed to the casing portion 110 with a screw, an adhesive, or the like. The casing portion 110 may be provided with a hole for fixing the base portion 120. The base portion 120 may be set to a ground potential. The base portion 120 has a principal surface in an XY plane.

A terminal arrangement surface 114 is a surface on which the plurality of terminals is provided on an upper surface side of the casing portion 110. On the terminal arrangement surface 114, a gate terminal 50, an emitter terminal 60, an auxiliary collector terminal 66, and a temperature sense terminal 80 may be provided. The terminal arrangement surface 114 has a protrusion 116 in a Z-axis direction.

The protrusion 116 is provided in a vicinity of a center of the terminal arrangement surface 114. The protrusion 116 extends in a longitudinal direction (an X-axis direction in the present example) of the terminal arrangement surface 114. On the protrusion 116, an external output terminal 70, an external positive electrode terminal 72, and an external negative electrode terminal 74 are provided. The external output terminal 70, the external positive electrode terminal 72, and the external negative electrode terminal 74 may form a current path for a great current flowing through a power device such as an IGBT. In a top view, an area of each of the external output terminal 70, the external positive electrode terminal 72, and the external negative electrode terminal 74 provided on the protrusion 116 may be greater than an area of each of the gate terminal 50, the emitter terminal 60, the auxiliary collector terminal 66, and the temperature sense terminal 80 provided on the terminal arrangement surface 114.

The external output terminal 70 is an alternating current output terminal. The external positive electrode terminal 72 is a positive side terminal of a direct current power source. The external negative electrode terminal 74 is a negative side terminal of the direct current power source. Each terminal may be electrically connected to a corresponding terminal of the semiconductor chip or the like included in the semiconductor device 100.

The gate terminal 50 supplies a gate voltage of a transistor portion described below. The emitter terminal 60 outputs an emitter voltage of the transistor portion. The auxiliary collector terminal 66 outputs a collector voltage of the transistor portion. The temperature sense terminal 80 is a terminal for a thermistor, which is connected to the thermistor embedded in the casing portion 110 and detects a temperature inside the casing portion 110.

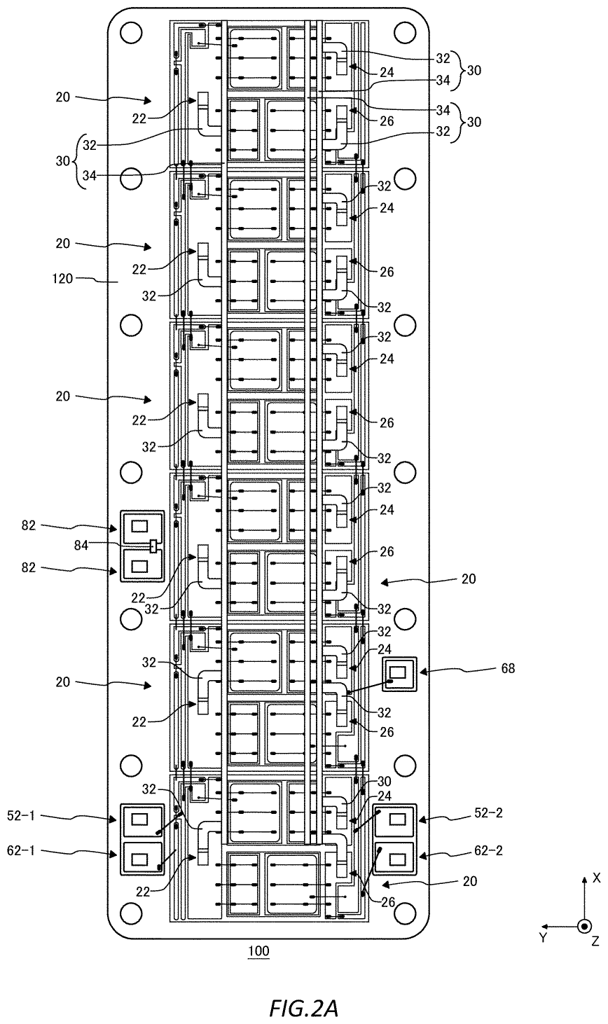

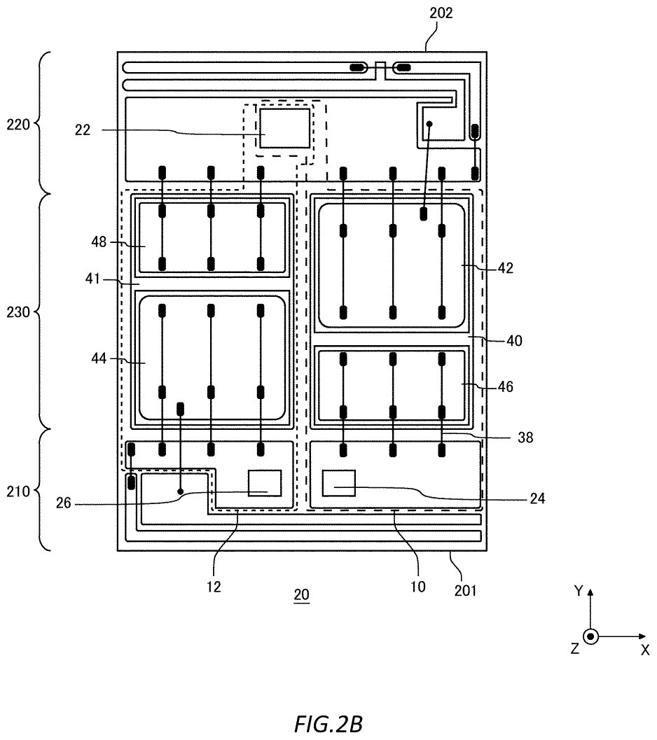

FIG. 2A shows an example of a plan view of the semiconductor device 100. This figure shows an arrangement example of a circuit provided on the base portion 120 inside the casing portion 110. The semiconductor device 100 includes one or more insulating plates 20 on the base portion 120.

The semiconductor device 100 of the present example includes six insulating plates 20 on the base portion 120. In the present example, the six insulating plates 20 are arranged side by side in the X-axis direction on the base portion 120. A plurality of semiconductor chips and a plurality of wiring patterns may be arranged on the insulating plate 20. In the present example, the plurality of insulating plates 20 is arranged on the base portion 120, but one insulating plate 20 may be arranged on the base portion 120.

The insulating plate 20 is bonded to the base portion 120. The insulating plate 20 may have conductive patterns on both surfaces of a ceramics (for example, alumina) substrate with favorable heat conductivity. For example, the insulating plate 20 is a direct copper bond (DCB) substrate in which a copper circuit board is directly bonded onto a ceramics substrate. Each of the insulating plates 20 is connected in parallel.

On the base portion 120, a gate connecting portion 52, an emitter connecting portion 62, an auxiliary collector connecting portion 68, and a temperature sense connecting portion 82 may be provided. Each connecting portion may be a circuit pattern provided on the base portion 120. Each connecting portion is connected to each terminal provided in the casing portion 110. The gate connecting portion 52 is connected to the gate terminal 50. The gate connecting portion 52 may have an upper arm side gate connecting portion 52-1 and a lower arm side gate connecting portion 52-2. The emitter connecting portion 62 is connected to the emitter terminal 60. The emitter connecting portion 62 may have an upper arm side emitter connecting portion 62-1 and a lower arm side emitter connecting portion 62-2. The auxiliary collector connecting portion 68 is connected to the auxiliary collector terminal 66. The temperature sense connecting portion 82 is connected to the temperature sense terminal 80.

The temperature sense connecting portion 82 may be connected to a temperature sense portion 84. The temperature sense portion 84 is a thermistor as an example.

Each of the insulating plates 20 of the semiconductor device 100 of the present example includes an output terminal 22, a positive electrode terminal 24, and a negative electrode terminal 26. Each terminal is electrically connected to each external terminal via a lead frame 30. The lead frame 30 has a leg portion 32 and a flat plate portion 34.

The output terminal 22 may be connected to the flat plate portion 34 via the leg portion 32. The flat plate portion 34 to which the output terminal 22 is connected may be connected to the external output terminal 70 at an upper portion in the casing portion 110.

The positive electrode terminal 24 may be connected to the flat plate portion 34 via the leg portion 32. The flat plate portion 34 to which the positive electrode terminal 24 is connected may be connected to the external positive electrode terminal 72 at an upper portion in the casing portion 110.

The negative electrode terminal 26 may be connected to the flat plate portion 34 via the leg portion 32. The flat plate portion 34 to which the negative electrode terminal 26 is connected may be connected to the external negative electrode terminal 74 at an upper portion in the casing portion 110.

The flat plate portion 34 to which the positive electrode terminal 24 is connected and the flat plate portion 34 to which the negative electrode terminal 26 is connected may form a parallel flat plate structure. This makes it possible to obtain favorable inductance characteristics of the semiconductor device 100.

FIG. 2B shows an example of the insulating plate 20 of the semiconductor device 100. The semiconductor device 100 includes a first wiring pattern 40 and a second wiring pattern 41. Each of the insulating plates 20 of the semiconductor device 100 of the present example is used for a current-fed inverter circuit having an upper arm circuit 10 and a lower arm circuit 12. The semiconductor device 100 of the present example may make up a 2in1 circuit of one phase of a three-phase power conversion circuit. Note that the semiconductor device 100 may make up a 1in1 circuit, or may make up a 6in1 circuit.

The first wiring pattern 40 is provided on the insulating plate 20. The first wiring pattern 40 may be formed of a conductive material including metal or the like. The first wiring pattern 40 may be made by directly bonding a copper plate, an aluminum plate, or a plate obtained by plating these materials or bonding such a plate via a brazing material layer to the insulating plate 20 of aluminum oxide ceramics, silicon nitride ceramics, aluminum nitride ceramics, or the like. A material of the first wiring pattern 40 may be alloy including at least any one of copper or aluminum. The material of the first wiring pattern 40 is copper as an example.

The second wiring pattern 41 is provided on the insulating plate 20, and is spaced apart from the first wiring pattern 40. The second wiring pattern 41 may be formed of a conductive material including metal or the like. The second wiring pattern 41 may be made by directly bonding a copper plate, an aluminum plate, or a plate obtained by plating these materials or bonding such a plate via a brazing material layer to the insulating plate 20 of aluminum oxide ceramics, silicon nitride ceramics, aluminum nitride ceramics, or the like. A material of the second wiring pattern 41 may be alloy including at least any one of copper or aluminum. The material of the second wiring pattern 41 is copper as an example.

The upper arm circuit 10 has a circuit in which the positive electrode terminal 24, a first diode portion 46, a first transistor portion 42, and the output terminal 22 are connected and arranged in this order. Note that the order of circuit connection included in the upper arm circuit 10 is not limited thereto.

The first diode portion 46 is provided on the first wiring pattern 40. The first diode portion 46 may be provided such that a cathode electrode contacts the first wiring pattern 40. An anode electrode of the first diode portion 46 may be connected to the positive electrode terminal 24 via a wire member 38.

The first transistor portion 42 is connected in series with the first diode portion 46, and is provided on the first wiring pattern 40. The first transistor portion 42 may be provided such that a collector electrode contacts the first wiring pattern 40. Since the collector electrode of the first transistor portion 42 and the cathode electrode of the first diode portion 46 are connected via the first wiring pattern 40, the first transistor portion 42 and the first diode portion 46 are connected in series. An emitter electrode of the first transistor portion 42 may be connected to the output terminal 22 via a wire member 38. The emitter electrode of the first transistor portion 42 may be connected to the upper arm side emitter connecting portion 62-1 via a wire member 38 or the like. A gate electrode of the first transistor portion 42 may be connected to the upper arm side gate connecting portion 52-1 via a wire member 38 or the like.

The lower arm circuit 12 has a second transistor portion 44 and a second diode portion 48. The lower arm circuit may have a circuit in which the output terminal 22, the second diode portion 48, the second transistor portion 44, and the negative electrode terminal 26 are connected and arranged in this order. Note that the order of circuit connection included in the lower arm circuit 12 is not limited thereto.

The second diode portion 48 is provided on the second wiring pattern 41. The second diode portion 48 may be provided such that a cathode electrode contacts the second wiring pattern 41. An anode electrode of the second diode portion 48 may be connected to the output terminal 22 via a wire member 38.

The second transistor portion 44 is connected in series with the second diode portion 48, and is provided on the second wiring pattern 41. The second transistor portion 44 may be provided such that a collector electrode contacts the second wiring pattern 41. The collector electrode of the second transistor portion 44 and the cathode electrode of the second diode portion 48 are connected via the second wiring pattern 41, so that the second transistor portion 44 and the second diode portion 48 are connected in series. An emitter electrode of the second transistor portion 44 may be connected to the negative electrode terminal 26 via a wire member 38. The emitter electrode of the second transistor portion 44 may be connected to the lower arm side emitter connecting portion 62-2 via a wire member 38 or the like. A gate electrode of the second transistor portion 44 may be connected to the lower arm side gate connecting portion 52-2 via a wire member 38 or the like.

The output terminal 22 may be provided on a positive side in a predetermined first direction with respect to the positive electrode terminal 24 and the negative electrode terminal 26. The output terminal 22 of the present example is provided on a positive side in a Y-axis direction with respect to the positive electrode terminal 24 and the negative electrode terminal 26. That is, the predetermined first direction of the present example is the Y-axis direction. The output terminal 22 may be provided on the positive side in the first direction with respect to the first wiring pattern 40 and the second wiring pattern 41. The output terminal 22 of the present example is provided on the positive side in the Y-axis direction with respect to the first wiring pattern 40 and the second wiring pattern 41.

The positive electrode terminal 24 may be provided on a negative side in the first direction with respect to the first wiring pattern 40 and the second wiring pattern 41. The positive electrode terminal 24 of the present example is provided on a negative side in the Y-axis direction with respect to the first wiring pattern 40 and the second wiring pattern 41.

The negative electrode terminal 26 may be provided on the negative side in the first direction with respect to the first wiring pattern 40 and the second wiring pattern 41. The negative electrode terminal 26 of the present example is provided on the negative side in the Y-axis direction with respect to the first wiring pattern 40 and the second wiring pattern 41.

The first wiring pattern 40 and the second wiring pattern 41 may be arrayed in a predetermined second direction different from the first direction. The first wiring pattern 40 and the second wiring pattern 41 of the present example are arrayed in the X-axis direction different from the Y-axis direction which is the first direction. That is, the predetermined second direction of the present example is the X-axis direction.

The first wiring pattern 40 may be provided on a positive side in the second direction with respect to the second wiring pattern 41. The first wiring pattern 40 of the present example is provided on a positive side in the X-axis direction with respect to the second wiring pattern 41.

The positive electrode terminal 24 may be provided on the positive side in the second direction with respect to the negative electrode terminal 26. The positive electrode terminal 24 of the present example is provided on the positive side in the X-axis direction with respect to the negative electrode terminal 26.

The order of the first wiring pattern 40 and the second wiring pattern 41 in the second direction and the order of the positive electrode terminal 24 and the negative electrode terminal 26 in the second direction may match each other. The upper arm circuit 10 of the present example includes the first transistor portion 42 and the first diode portion 46 provided on the first wiring pattern 40, and the positive electrode terminal 24. The lower arm circuit 12 of the present example includes the second transistor portion 44 and the second diode portion 48 provided on the second wiring pattern 41, and the negative electrode terminal 26. Accordingly, the upper arm circuit 10 and the lower arm circuit 12 are arrayed in the second direction, so that the order of the first wiring pattern 40 and the second wiring pattern 41 in the second direction and the order of the positive electrode terminal 24 and the negative electrode terminal 26 in the second direction may match each other. The upper arm circuit 10 of the present example is provided on the positive side in the X-axis direction which is the second direction with respect to the lower arm circuit 12.

The positive electrode terminal 24 and the negative electrode terminal 26 are provided in a first region 210 on the insulating plate 20. The first region 210 may be provided adjacent to a first end side 201 of the insulating plate 20.

The output terminal 22 is provided in a second region 220 different from the first region 210 on the insulating plate 20. The second region 220 may be provided adjacent to a second end side 202 of the insulating plate 20 opposing the first end side 201.

The first diode portion 46 may be provided in a third region 230 between the first region 210 and the second region 220 on the insulating plate 20. The first transistor portion 42 may be connected in series with the first diode portion 46 in the third region 230. The second diode portion 48 may be provided in the third region 230. The second transistor portion 44 may be connected in series with the second diode portion 48 in the third region 230.

The second region 220 may be provided on the positive side in the predetermined first direction with respect to the first region 210. That is, the output terminal 22 may be provided on the positive side in the predetermined first direction with respect to the positive electrode terminal 24 and the negative electrode terminal 26. The second region 220 of the present example is provided on the positive side in the Y-axis direction with respect to the first region 210. That is, the output terminal 22 of the present example is provided on the positive side in the Y-axis direction with respect to the positive electrode terminal 24 and the negative electrode terminal 26.

The first transistor portion 42 and the first diode portion 46, and the second transistor portion 44 and the second diode portion 48 may be arrayed in the predetermined second direction different from the first direction. The first transistor portion 42 and the first diode portion 46, and the second transistor portion 44 and the second diode portion 48 of the present example are arrayed in the X-axis direction different from the Y-axis direction which is the first direction. The first transistor portion 42 and the first diode portion 46 may be provided on the positive side in the second direction with respect to the second transistor portion 44 and the second diode portion 48. The first transistor portion 42 and the first diode portion 46 of the present example are provided on the positive side in the X-axis direction with respect to the second transistor portion 44 and the second diode portion 48.

The first transistor portion 42 may be provided on the positive side in the first direction with respect to the first diode portion 46. The first transistor portion 42 of the present example is provided on the positive side in the Y-axis direction with respect to the first diode portion 46. The second transistor portion 44 may be provided on the negative side in the first direction with respect to the second diode portion 48. The second transistor portion 44 of the present example is provided on the negative side in the Y-axis direction with respect to the second diode portion 48. Note that the arrangement of the first transistor portion 42 and the first diode portion 46 in the upper arm circuit 10 and the arrangement of the second transistor portion 44 and the second diode portion 48 in the lower arm circuit 12 are not limited thereto.

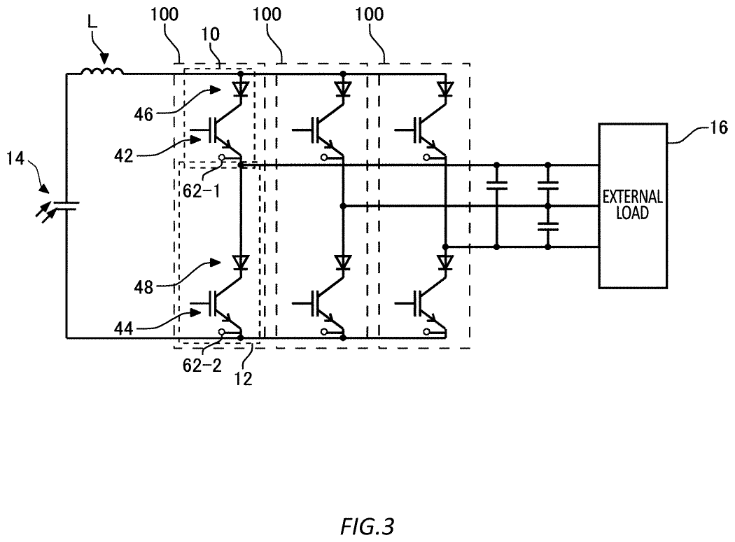

FIG. 3 shows an example of a configuration of the three-phase power conversion circuit. The semiconductor device 100 of the present example has the upper arm circuit 10 and the lower arm circuit 12, and makes up the 2in1 circuit of one phase of the three-phase power conversion circuit. In addition to three semiconductor devices 100, an inductor L may be provided on a high voltage power line to make up the current-fed inverter circuit.

The semiconductor device 100 may convert a direct current power from a power source 14 into a three-phase alternating current power, and supply such a power to an external load 16. The power source 14 may be a power obtained by solar power generation as an example. Since the semiconductor device 100 of the present example makes up the 2in1 circuit of one phase of the three-phase power conversion circuit, three semiconductor devices 100 are provided so that the three-phase power conversion circuit can be made. Also, the three-phase power conversion circuit of the present example can convert a low direct current voltage into a high alternating current voltage. Since the three-phase power conversion circuit of the present example is the current-fed inverter circuit, a constant current can be supplied to the load regardless of the external load 16.

For example, in a case where the power source 14 is a current source of predetermined amperes (for example, 100 A), an alternating current with a peak of 100 A flows through the external load 16. Assuming that the external load 16 has a predetermined impedance (for example, a resistance of 10Ω), the voltage generated by the external load 16 is 100 A×10 Ω=1000 V. Since a DC reactor (L×di/dt) by the inductor L and the direct current voltage of the power source 14 are applied to the external load 16, the voltage generated by the external load 16 is higher than the direct current voltage of the power source 14. Therefore, it is possible to output a voltage of the direct current voltage of the power source 14 or more to the external load 16 in FIG. 3.

In the upper arm circuit 10 of the present example, the first diode portion 46 and the first transistor portion 42 are connected in this order between the positive electrode terminal 24 and the output terminal 22, but the order of the first diode portion 46 and the first transistor portion 42 may be reversed. That is, the first transistor portion 42 may be connected on the positive electrode terminal 24 side, and the first diode portion 46 may be connected on the output terminal 22 side.

In the lower arm circuit 12 of the present example, the second diode portion 48 and the second transistor portion 44 are connected in this order between the output terminal 22 and the negative electrode terminal 26, but the order of the second diode portion 48 and the second transistor portion 44 may be reversed. That is, the second transistor portion 44 may be connected on the output terminal 22 side, and the second diode portion 48 may be connected on the negative electrode terminal 26 side.

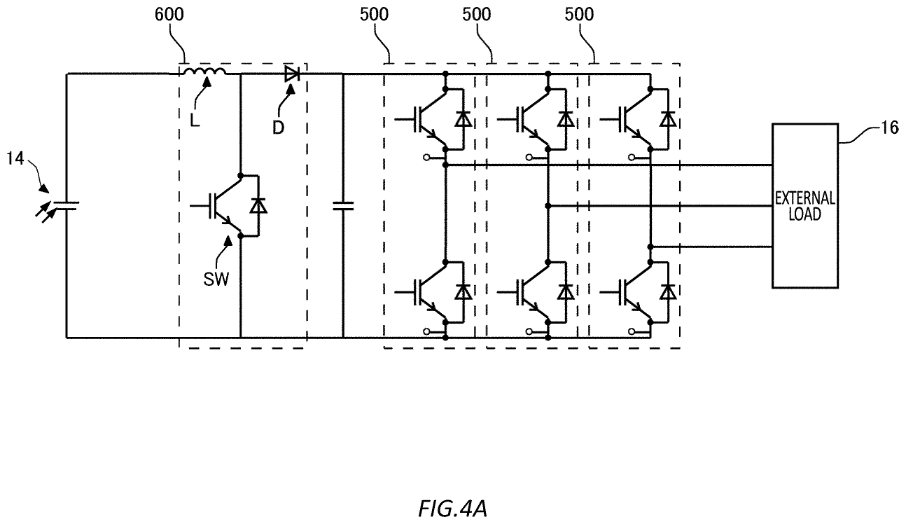

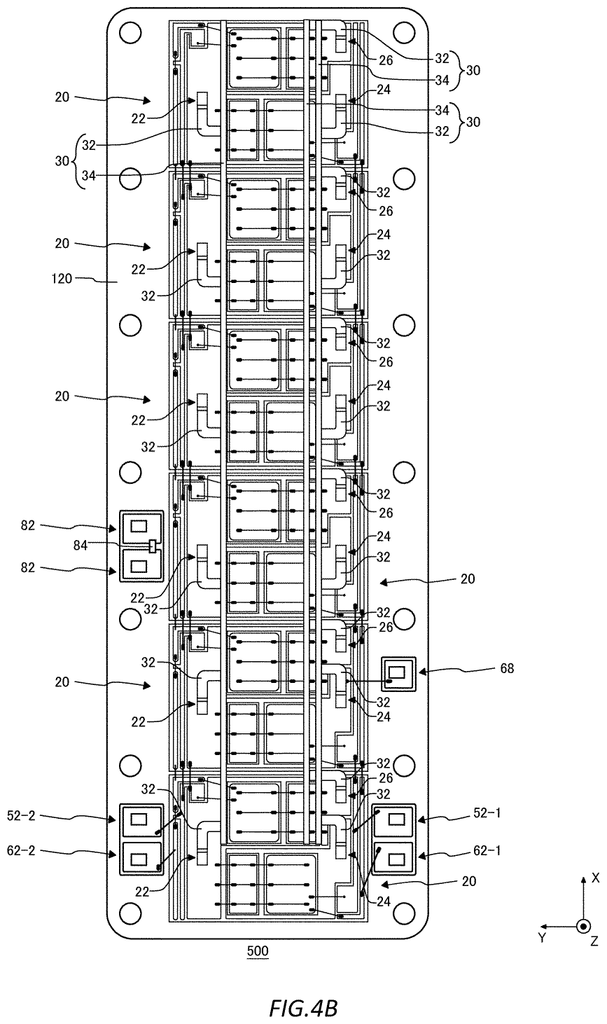

FIG. 4A shows an example of a configuration of a three-phase power conversion circuit according to a comparative example. A semiconductor device 500 according to the comparative example is a voltage-fed inverter circuit. In the comparative example, since an amplitude greater than an amplitude of a potential difference of an input DC voltage which is a power source voltage of a power source 14 cannot be obtained only with the voltage-fed inverter circuit, a boost converter 600 is provided. The boost converter 600 may have an inductor L, a diode D, and a switch SW. The boost converter 600 boosts the input DC voltage by controlling ON/OFF of the switch SW, so that the amplitude greater than the amplitude of the potential difference of the input DC voltage can be obtained. Since the voltage-fed inverter circuit does not have a voltage boosting function, a boost converter is required in a stage before a voltage-fed inverter in a case where an AC voltage higher than the input DC voltage is to be output.

Since the semiconductor device 100 according to the example is part of components of the current-fed inverter circuit, the three-phase power conversion circuit can be made without providing the separate boost converter 600 as compared to the case of using the semiconductor device 500 according to the comparative example, which includes the voltage-fed inverter circuit. This makes it possible to achieve cost reduction and space saving over an entire boost system. Also, the three-phase power conversion circuit can be made without using a special element such as a reverse blocking IGBT (RB-IGBT).

FIG. 4B shows an example of a plan view of the semiconductor device 500 according to the comparative example. In the semiconductor device 500 according to the comparative example, a positive electrode terminal 24 is provided on a negative side in an X-axis direction which is a second direction with respect to a negative electrode terminal 26. That is, an upper arm circuit 10 is provided on the negative side in the X-axis direction with respect to a lower arm circuit 12, and a first wiring pattern 40 is provided on the negative side in the X-axis direction with respect to a second wiring pattern 41. Also, an upper arm side gate connecting portion 52-1 and an upper arm side emitter connecting portion 62-1 are provided on a negative side in a Y-axis direction, and a lower arm side gate connecting portion 52-2 and a lower arm side emitter connecting portion 62-2 are provided on a positive side in the Y-axis direction. On the other hand, a position of a flat plate portion 34 of a lead frame 30 is similar to that of the semiconductor device 100 according to the example by changing a wiring of a leg portion 32 of the lead frame 30. Also, positions of an output terminal 22 and the lead frame 30 to which the output terminal 22 is connected are similar to those of the semiconductor device 100 according to the example. Accordingly, positions of an external output terminal 70, an external positive electrode terminal 72, and an external negative electrode terminal 74 provided on a protrusion 116 of a casing portion 110 are also similar.

The parallel flat plate structure formed of the flat plate portion 34 to which the positive electrode terminal 24 is connected and the flat plate portion 34 to which the negative electrode terminal 26 is connected in the semiconductor device 100 according to the example, which includes the current-fed inverter circuit is similar to a parallel flat plate structure formed of the flat plate portion 34 to which the positive electrode terminal 24 is connected and the flat plate portion 34 to which the negative electrode terminal 26 is connected in the semiconductor device 500 according to the comparative example, which includes the voltage-fed inverter circuit. This makes it possible to make the semiconductor device 100 according to the example without deterioration of the inductance characteristics from those of the semiconductor device 500 according to the comparative example. Also, since the position of each terminal provided in the casing portion 110 is not changed, the semiconductor device 100 according to the example can be adopted without changing the wiring and the like in implementation including the power source 14 and the external load 16 in the case of making the three-phase power conversion circuit.

As described above, the semiconductor device 100 according to the example, which includes the current-fed inverter circuit, can be substituted for the semiconductor device 500 according to the comparative example, which includes the voltage-fed inverter circuit, without deterioration of the inductance characteristics and without change in the wiring and the like in implementation. This makes it possible to improve compatibility between the semiconductor devices. Also, since the separate boost converter 600 is not required, cost reduction and space saving can be achieved over the entire boost system.

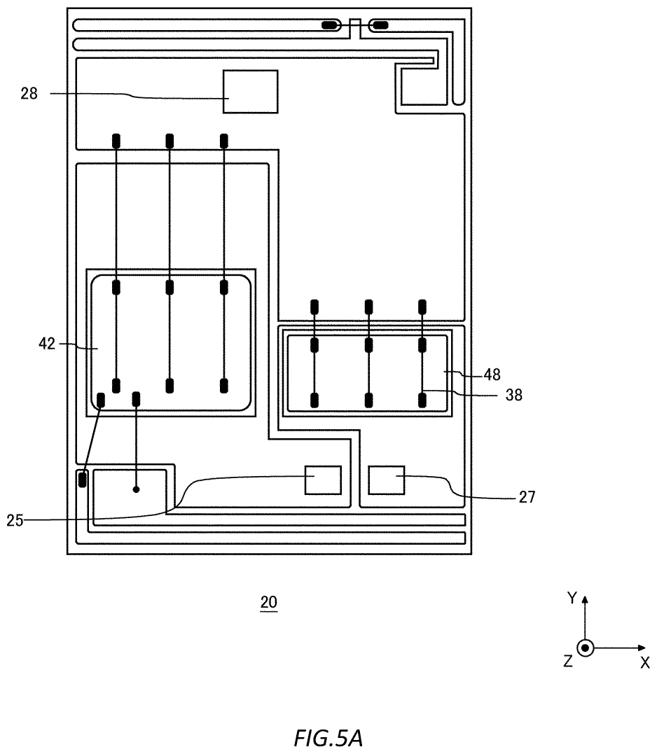

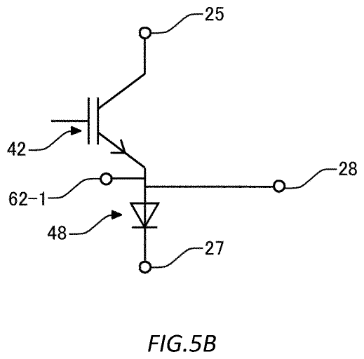

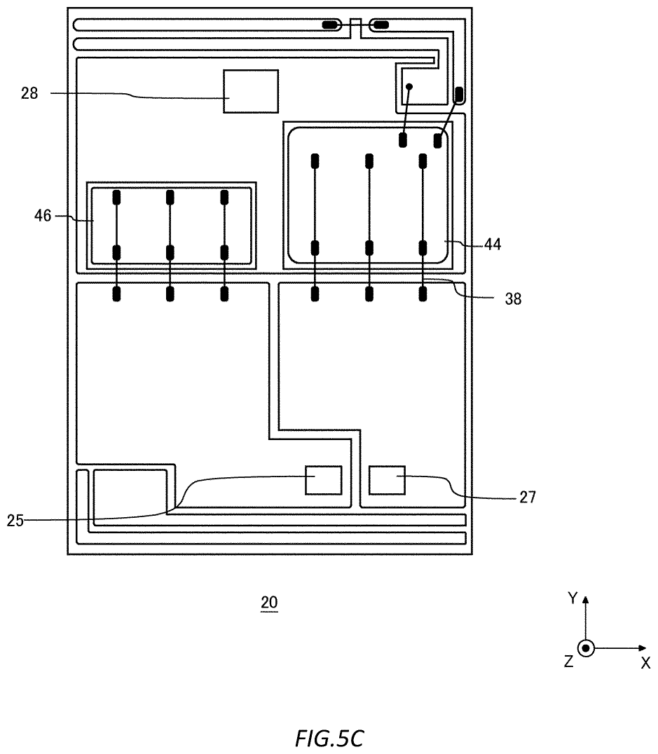

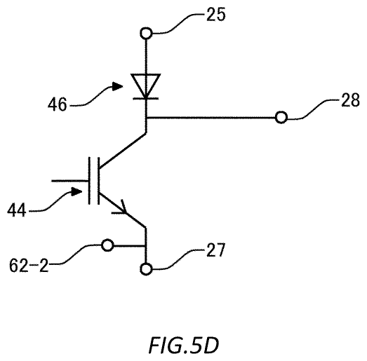

FIG. 5A shows an insulating plate 20 of a variation of the semiconductor device 100. The semiconductor device 100 of the present example is made such that the first diode portion 46 included in the upper arm circuit 10 and the second transistor portion 44 included in the lower arm circuit 12 are removed from the semiconductor device 500 according to the comparative example. Note that the first diode portion 46 included in the upper arm circuit 10 may not be removed, but be provided as a free wheeling diode for the first transistor portion 42. In a case where the first diode portion 46 is provided as the free wheeling diode for the first transistor portion 42, disruption of the first transistor portion 42 can be prevented.

The semiconductor device 100 includes a test terminal 28 connected between the first transistor portion 42 and the second diode portion 48. The output terminal 22 in the semiconductor device 500 according to the comparative example is the test terminal 28 in the present example. Also, the positive electrode terminal 24 according to the comparative example is a positive electrode side terminal 25 in the present example, and the negative electrode terminal 26 according to the comparative example is a negative electrode side terminal 27 in the present example. In the semiconductor device 100 of the present example, since the second transistor portion 44 included in the lower arm circuit 12 is removed from the semiconductor device 500 according to the comparative example and the output terminal 22 of the comparative example is the test terminal 28, the lower arm side gate connecting portion 52-2 and the lower arm side emitter connecting portion 62-2, and the gate terminal 50 and the emitter terminal 60 connected thereto may not be used.

Since the output terminal 22 of the comparative example is the test terminal 28, the semiconductor device 100 of the present example can be made without changing an appearance of a package from that of the semiconductor device 500 according to the comparative example. This makes it possible to improve the compatibility between the semiconductor devices.

The semiconductor device 100 of the present example makes up the upper arm circuit 10 or the lower arm circuit 12 in FIG. 3. In a case where the semiconductor device 100 makes up the upper arm circuit 10 in FIG. 3, the positive electrode side terminal 25 of the present example corresponds to the positive electrode terminal 24 according to the example in FIG. 2B, and the negative electrode side terminal 27 of the present example corresponds to the output terminal 22 according to the example in FIG. 2B. In a case where the semiconductor device 100 makes up the lower arm circuit 12 in FIG. 3, the positive electrode side terminal 25 of the present example corresponds to the output terminal 22 according to the example in FIG. 2B, and the negative electrode side terminal 27 of the present example corresponds to the negative electrode terminal 26 according to the example in FIG. 2B. In the case where the semiconductor device 100 makes up either the upper arm circuit 10 or the lower arm circuit 12, the positive electrode side terminal 25 may be provided on the positive electrode side with respect to the negative electrode side terminal 27.

FIG. 5B shows a circuit configuration of the variation of the semiconductor device 100. The semiconductor device 100 of the present example includes the first transistor portion 42, the second diode portion 48 connected in series with the first transistor portion 42, and the test terminal 28 connected between the first transistor portion 42 and the second diode portion 48. The semiconductor device 100 of the present example makes up the upper arm circuit 10 or the lower arm circuit 12 in FIG. 3. The semiconductor device 100 of the present example includes the test terminal 28, so that a characteristic test can be performed on each element even after the semiconductor device 100 was made.

FIG. 5C shows an insulating plate 20 of a variation of the semiconductor device 100. The semiconductor device 100 of the present example is made such that the first transistor portion 42 included in the upper arm circuit 10 and the second diode portion 48 included in the lower arm circuit 12 are removed from the semiconductor device 500 according to the comparative example. Note that the second diode portion 48 included in the lower arm circuit 12 may not be removed, but be provided as a free wheeling diode for the second transistor portion 44. In a case where the second diode portion 48 is provided as the free wheeling diode for the second transistor portion 44, disruption of the second transistor portion 44 can be prevented. The semiconductor device 100 of the present example makes up the upper arm circuit 10 or the lower arm circuit 12.

The semiconductor device 100 includes a test terminal 28 connected between the second transistor portion 44 and the first diode portion 46. The output terminal 22 in the semiconductor device 500 according to the comparative example is the test terminal 28 in the present example. Also, the positive electrode terminal 24 according to the comparative example is a positive electrode side terminal 25 in the present example, and the negative electrode terminal 26 according to the comparative example is a negative electrode side terminal 27 in the present example. In the semiconductor device 100 of the present example, since the first transistor portion 42 included in the upper arm circuit 10 is removed from the semiconductor device 500 according to the comparative example and the output terminal 22 of the comparative example is the test terminal 28, the upper arm side gate connecting portion 52-1 and the upper arm side emitter connecting portion 62-1, and the gate terminal 50 and the emitter terminal 60 connected thereto may not be used.

Since the role of each terminal is changed, the semiconductor device 100 of the present example can be made without changing the appearance of the package from that of the semiconductor device 500 according to the comparative example. This makes it possible to improve the compatibility between the semiconductor devices.

FIG. 5D shows a circuit configuration of the variation of the semiconductor device 100. The upper arm circuit 10 or the lower arm circuit 12 as the semiconductor device 100 of the present example includes the second transistor portion 44, the first diode portion 46 connected in series with the second transistor portion 44, and the test terminal 28 connected between the second transistor portion 44 and the first diode portion 46. The semiconductor device 100 of the present example includes the test terminal 28, so that the characteristic test can be performed on each element even after the semiconductor device 100 was made.

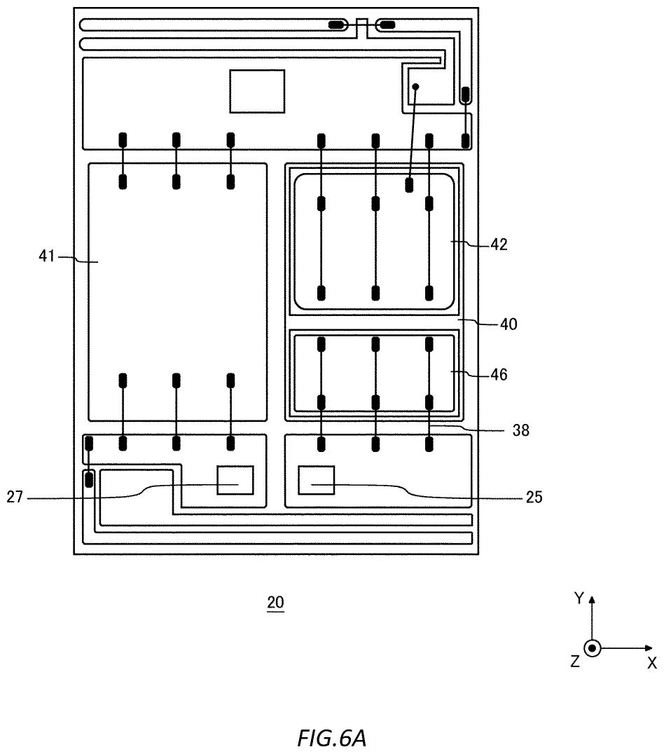

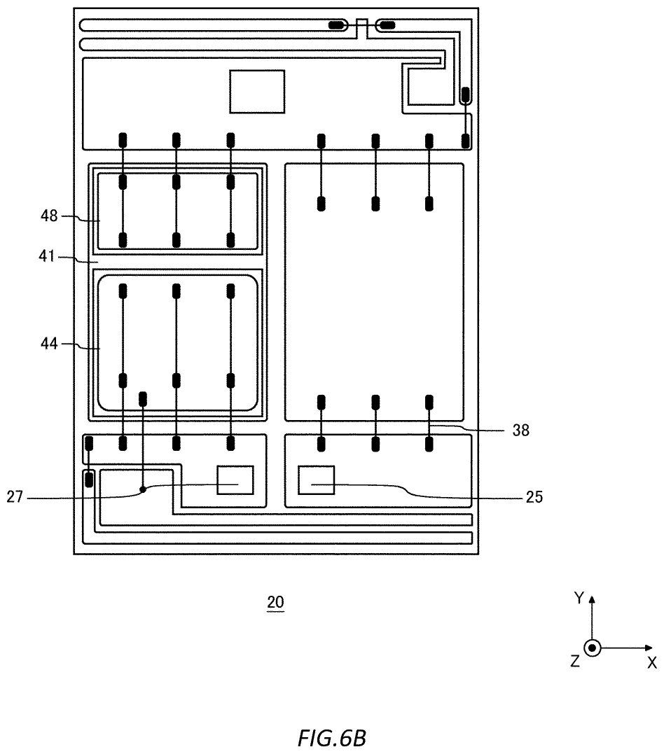

FIG. 6A shows an insulating plate 20 of a variation of the semiconductor device 100. The semiconductor device 100 of the present example is made such that the second transistor portion 44 and the second diode portion 48 included in the lower arm circuit 12 are removed from the semiconductor device 100 according to the example of FIG. 2B, and makes up the upper arm circuit 10 or the lower arm circuit 12. In the semiconductor device 100 of the present example, since the second transistor portion 44 included in the lower arm circuit 12 is removed from the semiconductor device 100 according to the example of FIG. 2B, the lower arm side gate connecting portion 52-2 and the lower arm side emitter connecting portion 62-2, and the gate terminal 50 and the emitter terminal 60 connected thereto may not be used. Also in the present example, the semiconductor device 100 can be made without changing the appearance of the package, and the compatibility between the semiconductor devices can be improved.

FIG. 6B shows an insulating plate 20 of a variation of the semiconductor device 100. The semiconductor device 100 of the present example is made such that the first transistor portion 42 and the first diode portion 46 included in the upper arm circuit 10 are removed from the semiconductor device 100 according to the example of FIG. 2B, and makes up the upper arm circuit 10 or the lower arm circuit 12. In the semiconductor device 100 of the present example, since the first transistor portion 42 included in the upper arm circuit 10 is removed from the semiconductor device 100 according to the example of FIG. 2B, the upper arm side gate connecting portion 52-1 and the upper arm side emitter connecting portion 62-1, and the gate terminal 50 and the emitter terminal 60 connected thereto may not be used. Also in the present example, the semiconductor device 100 can be made without changing the appearance of the package, and the compatibility between the semiconductor devices can be improved.

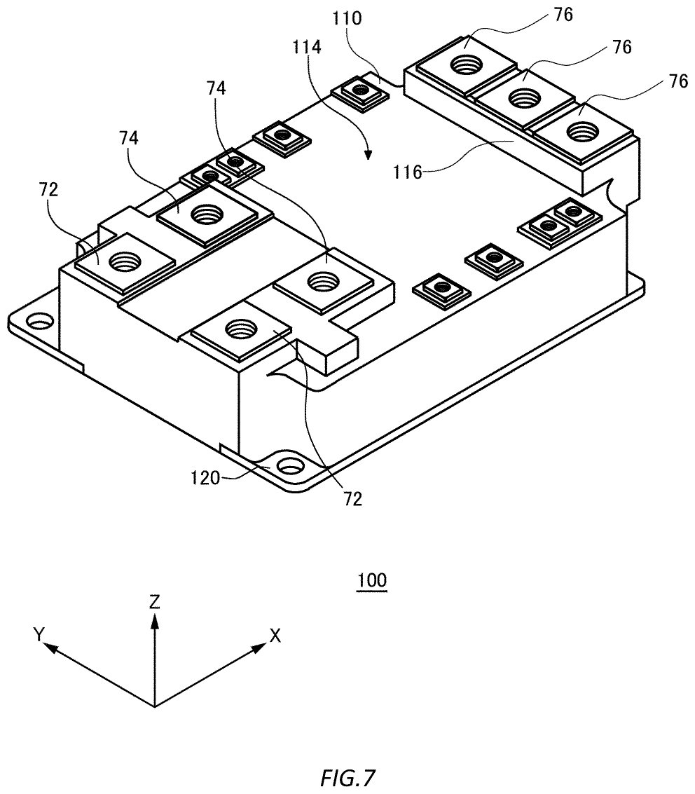

FIG. 7 shows a perspective view of a variation of the semiconductor device 100. The semiconductor device 100 of the present example is different from that of the example of FIG. 1 in the appearance of the package. The semiconductor device 100 of the present example includes the external positive electrode terminal 72, the external negative electrode terminal 74, and an external test terminal 76. The external test terminal 76 is a direct current terminal for performing the characteristic test on each element.

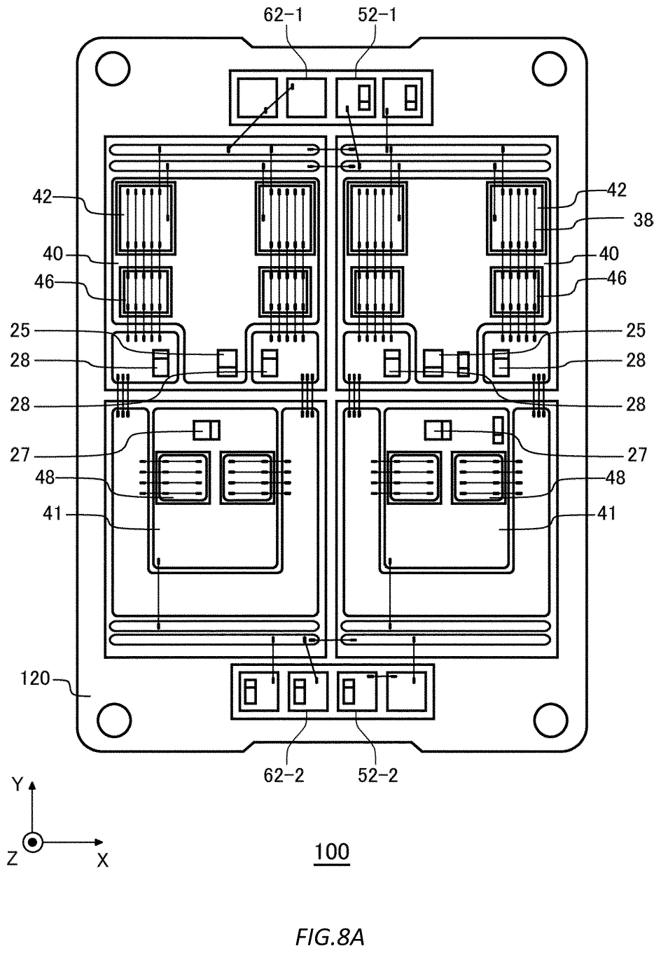

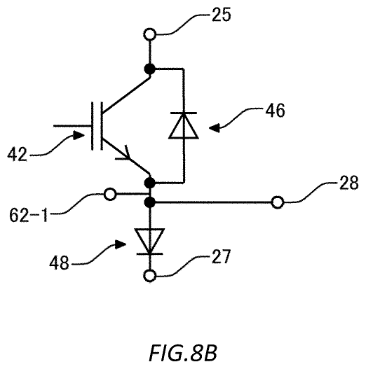

FIG. 8A shows a plan view of a variation of the semiconductor device 100. The semiconductor device 100 of the present example includes a positive electrode side terminal 25, a negative electrode side terminal 27, and a test terminal 28. The positive electrode side terminal 25 is electrically connected to the external positive electrode terminal 72. The negative electrode side terminal 27 is electrically connected to the external negative electrode terminal 74. The test terminal 28 is electrically connected to an external test terminal 76. The semiconductor device 100 may includes the first transistor portion 42, the first diode portion 46, and the second diode portion 48. In a case where the first diode portion 46 is provided as a free wheeling diode for the first transistor portion 42, disruption of the first transistor portion 42 can be prevented. Note that the first diode portion 46 may not be provided. The semiconductor device 100 of the present example makes up the upper arm circuit 10 or the lower arm circuit 12.

The first diode portion 46 is provided on the first wiring pattern 40. The first diode portion 46 may be provided such that the cathode electrode contacts the first wiring pattern 40. The anode electrode of the first diode portion 46 may be connected to the test terminal 28 via a wire member 38.

The first transistor portion 42 is connected in parallel with the first diode portion 46, and is provided on the first wiring pattern 40. The first transistor portion 42 may be provided such that the collector electrode contacts the first wiring pattern 40. The emitter electrode of the first transistor portion 42 may be connected to the anode electrode of the first diode portion 46 via a wire member 38. The collector electrode of the first transistor portion 42 and the cathode electrode of the first diode portion 46 are connected via the first wiring pattern 40 and the emitter electrode of the first transistor portion 42 and the anode electrode of the first diode portion 46 are connected via the wire member 38 such that the first transistor portion 42 and the first diode portion 46 are connected in parallel.

The second diode portion 48 is provided on the second wiring pattern 41. The second diode portion 48 may be provided such that the cathode electrode contacts the second wiring pattern 41. The anode electrode of the second diode portion 48 may be connected to the test terminal 28 via a wire member 38.

In the semiconductor device 100 of the present example, only the second diode portion 48 is provided on the negative side in the Y-axis direction, and the second transistor portion 44 is not provided. Accordingly, the upper arm side gate connecting portion 52-1 and the upper arm side emitter connecting portion 62-1 are used, but the lower arm side gate connecting portion 52-2 and the lower arm side emitter connecting portion 62-2 may not be used. Note that the lower arm side emitter connecting portion 62-2 may be connected to the anode electrode of the second diode portion 48, and be used as an auxiliary terminal.

FIG. 8B shows a circuit configuration of the variation of the semiconductor device 100. The upper arm circuit 10 or the lower arm circuit 12 of the present example includes the first transistor portion 42, the first diode portion 46 connected in parallel with the first transistor portion 42, the second diode portion 48 connected in series with the first transistor portion 42, and a test terminal 28 connected between the first transistor portion 42 and the second diode portion 48. In a case where the first diode portion 46 is provided as a free wheeling diode for the first transistor portion 42, disruption of the first transistor portion 42 can be prevented. Note that the first diode portion 46 may not be provided. The semiconductor device 100 of the present example includes the test terminal 28, so that the characteristic test can be performed on each element even after the semiconductor device 100 was made.

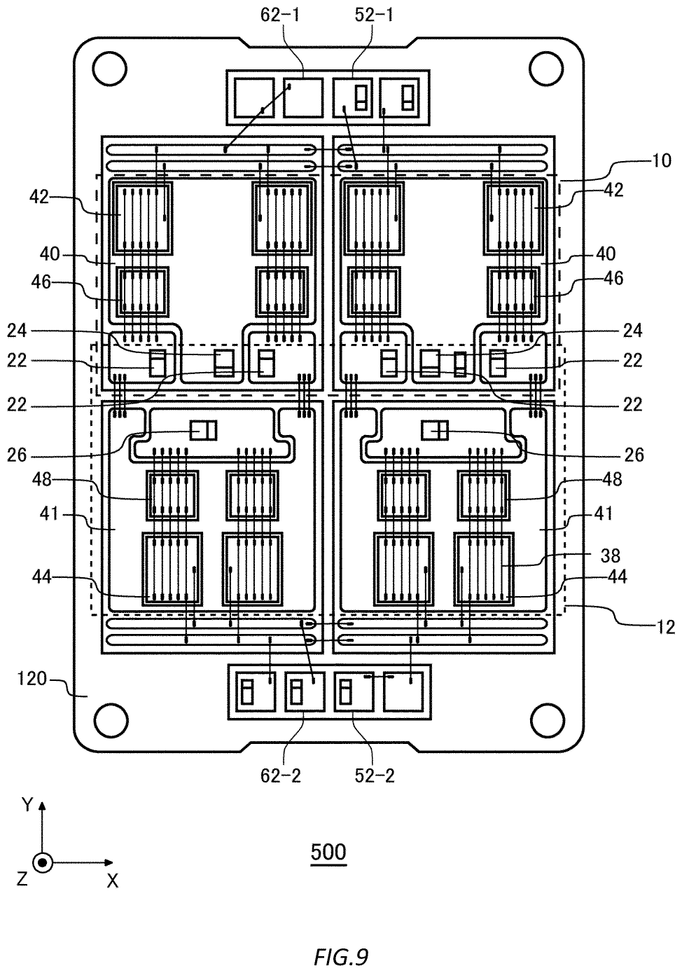

FIG. 9 shows a plan view of a semiconductor device 500 according to a comparative example. The semiconductor device 500 according to the comparative example includes an output terminal 22, a positive electrode terminal 24, and a negative electrode terminal 26. The semiconductor device 500 may include a second transistor portion 44 provided on a second wiring pattern 41 and connected in parallel with a second diode portion 48. The semiconductor device 500 according to the comparative example makes up an upper arm circuit and a lower arm circuit of a voltage-fed inverter circuit. A circuit configuration may be similar to that of the semiconductor device 500 of FIG. 4A.

The semiconductor device 100 according to the example of FIG. 8A is made such that the second transistor portion 44 included in the lower arm circuit 12 is removed from the semiconductor device 500 according to the comparative example of FIG. 9. Note that the first diode portion 46 included in the upper arm circuit 10 may be removed. Alternatively, the semiconductor device 100 according to the example of FIG. 8A may be made such that the first transistor portion 42 included in the upper arm circuit 10 and/or the second diode portion 48 included in the lower arm circuit 12 are removed from the semiconductor device 500 according to the comparative example of FIG. 9. The output terminal 22 in the comparative example of FIG. 9 is the test terminal 28 in the present example of FIG. 8A. Also, the positive electrode terminal 24 according to the comparative example of FIG. 9 is the positive electrode side terminal 25 in the example of FIG. 8A, and the negative electrode terminal 26 according to the comparative example of FIG. 9 is the negative electrode side terminal 27 in the example of FIG. 8A.

Since the role of each terminal is changed, the semiconductor device 100 according to the example of FIG. 8A can be made without changing the appearance of the package from that of the semiconductor device 500 according to the comparative example of FIG. 9. This makes it possible to improve the compatibility between the semiconductor devices.

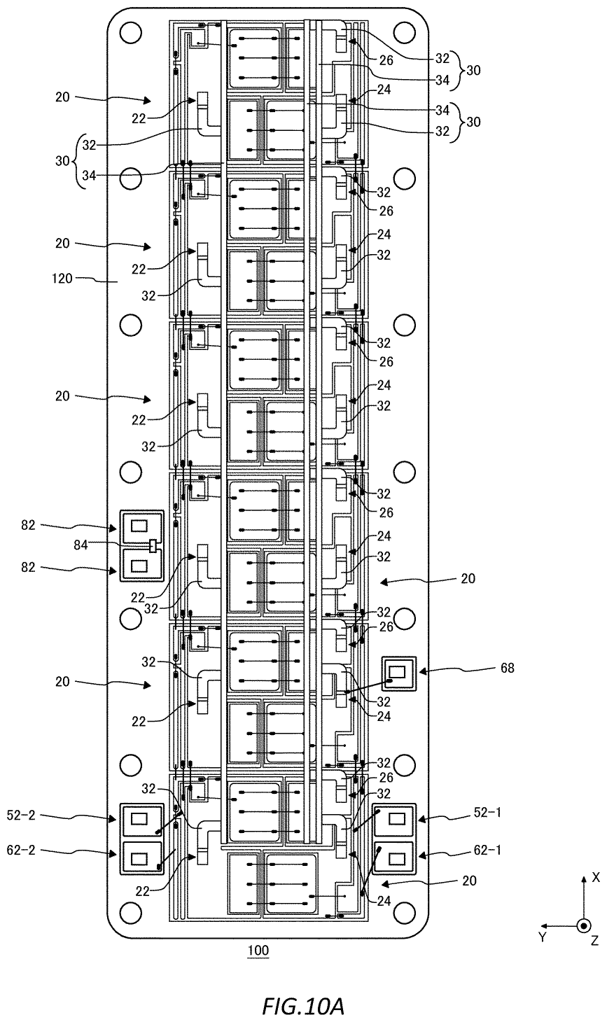

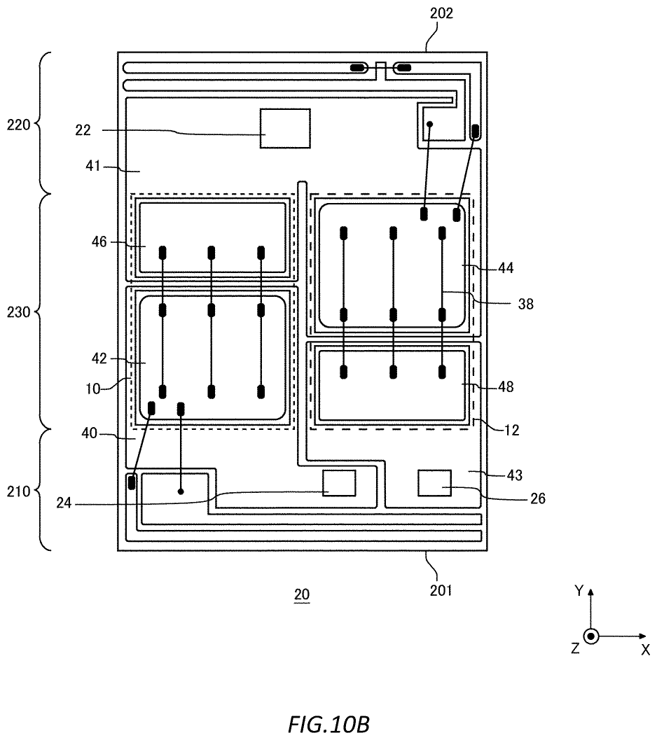

FIG. 10A shows a plan view of a variation of the semiconductor device 100. The semiconductor device 100 of the present example is different from that of the example of FIG. 2A in the configuration of the insulating plate 20, the configuration of the lead frame 30, and the arrangement of the gate connecting portion 52 and the emitter connecting portion 62. In the present example, the differences from the example of FIG. 2A will be particularly described, and other configurations may be the same as those in the example of FIG. 2A. Note that details of the difference in the configuration of the insulating plate 20 will be described below.

The positive electrode terminal 24 of the present example is provided on the negative side in the X-axis direction with respect to the negative electrode terminal 26. That is, as described below, the upper arm circuit 10 is provided on the negative side in the X-axis direction with respect to the lower arm circuit 12. Accordingly, the arrangements of the upper arm side gate connecting portion 52-1 and the upper arm side emitter connecting portion 62-1, and the lower arm side gate connecting portion 52-2 and the lower arm side emitter connecting portion 62-2 are reversed from those of the example of FIG. 2A. On the other hand, the position of the flat plate portion 34 of the lead frame 30 is similar to that of the example of FIG. 2A by changing the wiring of the leg portion 32 of the lead frame 30. Accordingly, the positions of the external output terminal 70, the external positive electrode terminal 72, and the external negative electrode terminal 74 provided on the protrusion 116 of the casing portion 110 are also similar.

Also, in the present example, the arrangements of the upper arm side gate connecting portion 52-1 and the upper arm side emitter connecting portion 62-1, and the lower arm side gate connecting portion 52-2 and the lower arm side emitter connecting portion 62-2 are similar to those of the comparative example of FIG. 4B. That is, the configurations of the leg portion 32 and the flat plate portion 34 of the lead frame 30 are similar to those of the semiconductor device 500 according to the comparative example, and the positions of the gate terminal 50, the emitter terminal 60, the external output terminal 70, the external positive electrode terminal 72, and the external negative electrode terminal 74 provided in the casing portion 110 are also similar to those of the semiconductor device 500 according to the comparative example.

FIG. 10B shows an insulating plate 20 of a variation of the semiconductor device 100. The semiconductor device 100 of the present example is different from that of the example of FIG. 2B in the order of the upper arm circuit 10 and the lower arm circuit 12 in the X-axis direction. In the present example, the differences from the example of FIG. 2B will be particularly described, and other configurations may be the same as those in the example of FIG. 2B.

The upper arm circuit 10 has the first transistor portion 42 and the first diode portion 46. The positive electrode terminal 24, the first transistor portion 42, the first diode portion 46, and the output terminal 22 may be electrically connected in this order. Note that the order of circuit connection is not limited thereto.

The collector electrode of the first transistor portion 42 may be electrically connected to the positive electrode terminal 24 via the first wiring pattern 40.

The cathode electrode of the first diode portion 46 may be electrically connected to the output terminal 22 via the second wiring pattern 41. Since the emitter electrode of the first transistor portion 42 and the anode electrode of the first diode portion 46 are electrically connected via the wire member 38, the first transistor portion 42 and the first diode portion 46 are connected in series. The emitter electrode of the first transistor portion 42 may be electrically connected to the upper arm side emitter connecting portion 62-1 via the wire member 38 or the like. The gate electrode of the first transistor portion 42 may be electrically connected to the upper arm side gate connecting portion 52-1 via the wire member 38 or the like.

The lower arm circuit 12 has the second transistor portion 44 and the second diode portion 48. The output terminal 22, the second transistor portion 44, the second diode portion 48, and the negative electrode terminal 26 may be electrically connected in this order. Note that the order of circuit connection is not limited thereto.

The collector electrode of the second transistor portion 44 may be electrically connected to the output terminal 22 via the second wiring pattern 41. The cathode electrode of the second diode portion 48 may be electrically connected to the negative electrode terminal 26 via a third wiring pattern 43. Since the emitter electrode of the second transistor portion 44 and the anode electrode of the second diode portion 48 are electrically connected via the wire member 38, the second transistor portion 44 and the second diode portion 48 are connected in series. The emitter electrode of the second transistor portion 44 may be electrically connected to the lower arm side emitter connecting portion 62-2 via the wire member 38 or the like. The gate electrode of the second transistor portion 44 may be electrically connected to the lower arm side gate connecting portion 52-2 via the wire member 38 or the like.

The first transistor portion 42 and the first diode portion 46, and the second transistor portion 44 and the second diode portion 48 may be arrayed in the predetermined second direction different from the first direction. The first transistor portion 42 and the first diode portion 46, and the second transistor portion 44 and the second diode portion 48 of the present example are arrayed in the X-axis direction different from the Y-axis direction which is the first direction. The first transistor portion 42 and the first diode portion 46 may be provided on the negative side in the second direction with respect to the second transistor portion 44 and the second diode portion 48. The first transistor portion 42 and the first diode portion 46 of the present example are provided on the negative side in the X-axis direction with respect to the second transistor portion 44 and the second diode portion 48.

The positive electrode terminal 24 may be provided on the negative side in the second direction with respect to the negative electrode terminal 26. The positive electrode terminal 24 of the present example is provided on the negative side in the X-axis direction with respect to the negative electrode terminal 26.

The orders of the first transistor portion 42 and the first diode portion 46, and the second transistor portion 44 and the second diode portion 48 in the second direction and the order of the positive electrode terminal 24 and the negative electrode terminal 26 in the second direction may match each other. The upper arm circuit 10 of the present example has the first transistor portion 42 and the first diode portion 46. The lower arm circuit 12 of the present example has the second transistor portion 44 and the second diode portion 48. Accordingly, the order of the upper arm circuit 10 and the lower arm circuit 12 in the second direction and the order of the positive electrode terminal 24 and the negative electrode terminal 26 in the second direction may match each other. The upper arm circuit 10 of the present example is provided on the negative side in the X-axis direction which is the second direction with respect to the lower arm circuit 12.

The first transistor portion 42 may be provided on the negative side in the first direction with respect to the first diode portion 46. The first transistor portion 42 of the present example is provided on the negative side in the Y-axis direction with respect to the first diode portion 46. The second transistor portion 44 may be provided on the positive side in the first direction with respect to the second diode portion 48. The second transistor portion 44 of the present example is provided on the positive side in the Y-axis direction with respect to the second diode portion 48. Note that the arrangement of the first transistor portion 42 and the first diode portion 46 in the upper arm circuit 10 and the arrangement of the second transistor portion 44 and the second diode portion 48 in the lower arm circuit 12 are not limited thereto.

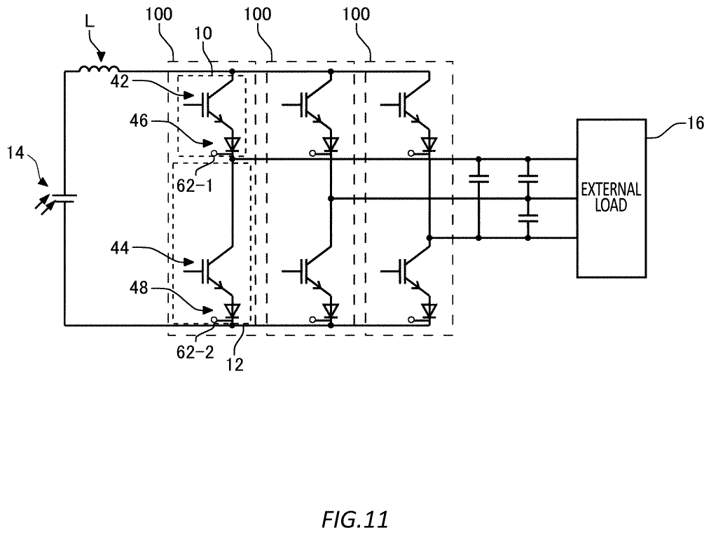

FIG. 11 shows a variation of the configuration of the three-phase power conversion circuit. The three-phase power conversion circuit of the present example is different from that of the example of FIG. 3 in the order of connection of the transistor portion and the diode portion. Other configurations may be the same as those in the example of FIG. 3.

The semiconductor devices 100 according to the examples described by using FIGS. 10A to 11 can also be substituted for the semiconductor device 500 according to the comparative example described by using FIGS. 4A and 4B without deterioration of the inductance characteristics and change in the wiring and the like in implementation. This makes it possible to improve the compatibility between the semiconductor devices. Also, since the separate boost converter 600 is not required, cost reduction and space saving can be achieved over the entire boost system.

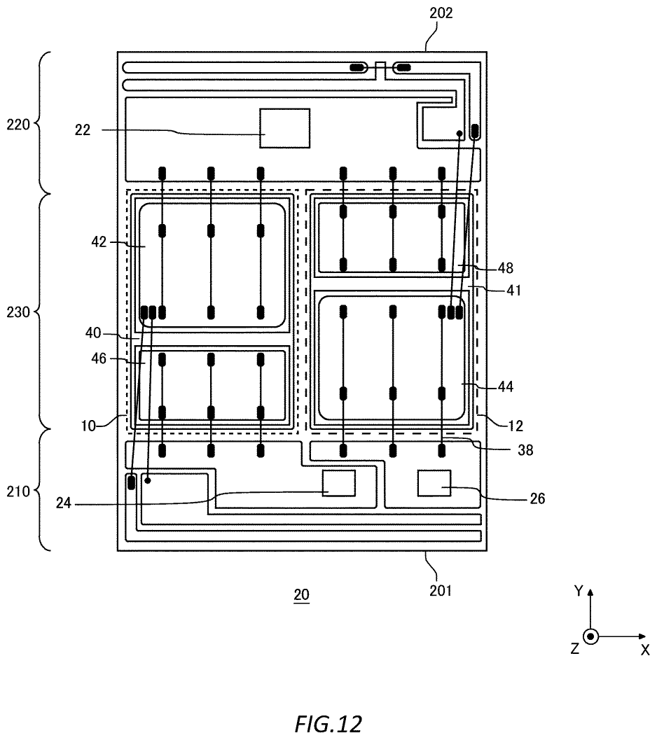

FIG. 12 shows an insulating plate 20 of a variation of the semiconductor device 100. The semiconductor device 100 of the present example is different from that of the example of FIG. 10B in the arrangement of the transistor portion and the diode portion in the upper arm circuit 10 and the lower arm circuit 12. In the present example, the differences from the example of FIG. 10B will be particularly described, and other configurations may be the same as those in the example of FIG. 10B.

The first transistor portion 42 may be provided on the positive side in the first direction with respect to the first diode portion 46. The first transistor portion 42 of the present example is provided on the positive side in the Y-axis direction with respect to the first diode portion 46. That is, the order of the first transistor portion 42 and the first diode portion 46 in the Y-axis direction is opposite to that of the example of FIG. 10B. The second transistor portion 44 may be provided on the negative side in the first direction with respect to the second diode portion 48. The second transistor portion 44 of the present example is provided on the negative side in the Y-axis direction with respect to the second diode portion 48. That is, the order of the second transistor portion 44 and the second diode portion 48 in the Y-axis direction is opposite to that of the example of FIG. 10B. In this manner, the arrangement of the first transistor portion 42 and the first diode portion 46 in the upper arm circuit 10 and the arrangement of the second transistor portion 44 and the second diode portion 48 in the lower arm circuit 12 may be any arrangement.

The emitter electrode of the first transistor portion 42 may be electrically connected to the output terminal 22 via the wire member 38. The anode electrode of the first diode portion 46 may be electrically connected to the positive electrode terminal 24 via the wire member 38. Since the collector electrode of the first transistor portion 42 and the cathode electrode of the first diode portion 46 are electrically connected via the first wiring pattern 40, the first transistor portion 42 and the first diode portion 46 are connected in series.

The emitter electrode of the second transistor portion 44 may be electrically connected to the negative electrode terminal 26 via the wire member 38. The anode electrode of the second diode portion 48 may be electrically connected to the output terminal 22 via the wire member 38. Since the collector electrode of the second transistor portion 44 and the cathode electrode of the second diode portion 48 are electrically connected via the second wiring pattern 41, the second transistor portion 44 and the second diode portion 48 are connected in series.

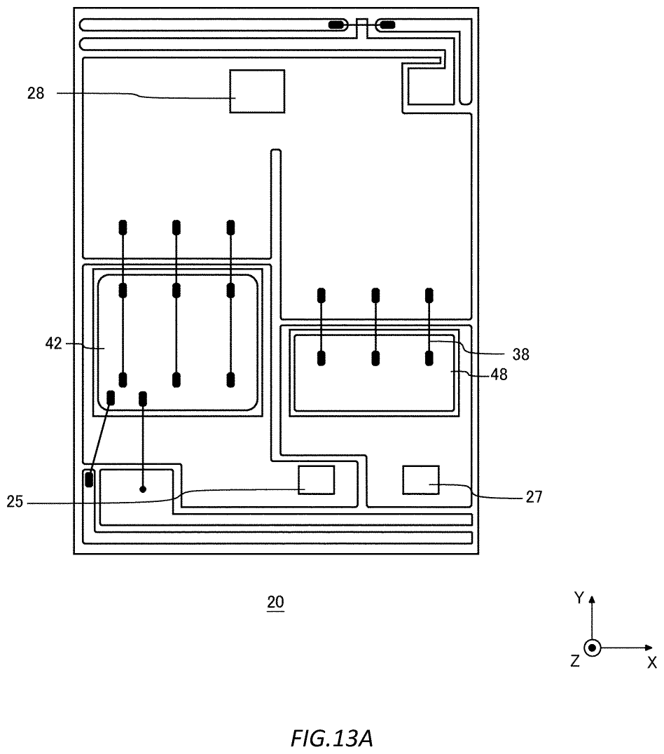

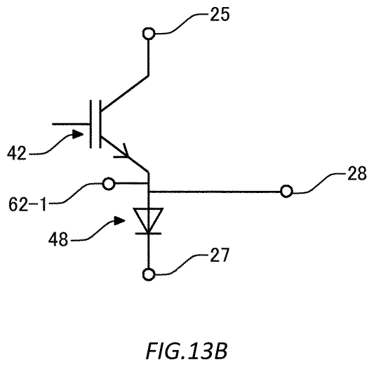

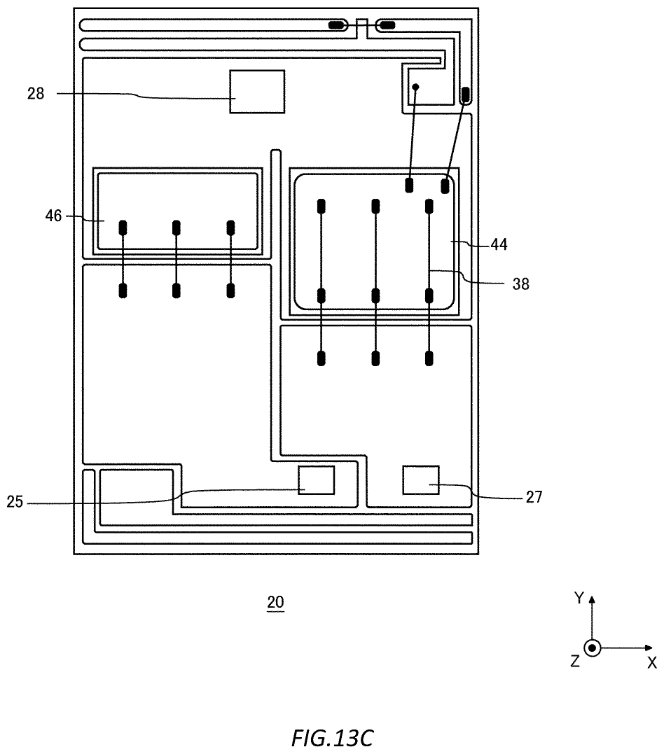

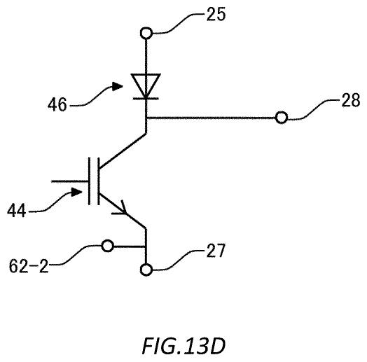

FIG. 13A shows an insulating plate 20 of a variation of the semiconductor device 100. The semiconductor device 100 of the present example is made such that the first diode portion 46 included in the upper arm circuit 10 and the second transistor portion 44 included in the lower arm circuit 12 are removed from the semiconductor device 100 according to the example of FIG. 10B. The semiconductor device 100 of the present example makes up the upper arm circuit 10 or the lower arm circuit 12 of FIG. 11.

The semiconductor device 100 includes a test terminal 28 connected between the first transistor portion 42 and the second diode portion 48. The output terminal 22 in the semiconductor device 100 according to the example of FIG. 10B is the test terminal 28 in the present example. Also, the positive electrode terminal 24 according to the example of FIG. 10B is a positive electrode side terminal 25 in the present example, and the negative electrode terminal 26 according to the example of FIG. 10B is a negative electrode side terminal 27 in the present example. In the semiconductor device 100 of the present example, since the second transistor portion 44 included in the lower arm circuit 12 is removed from the semiconductor device 100 according to the example of FIG. 10B and the output terminal 22 of the example of FIG. 10B is the test terminal 28, the lower arm side gate connecting portion 52-2 and the lower arm side emitter connecting portion 62-2, and the gate terminal 50 and the emitter terminal 60 connected thereto may not be used.

Since the role of each terminal is changed, the semiconductor device 100 of the present example can be made without changing the appearance of the package from that of the semiconductor device 100 according to the example of FIG. 10B. This makes it possible to improve the compatibility between the semiconductor devices.

FIG. 13B shows a circuit configuration of the variation of the semiconductor device 100. The semiconductor device 100 of the present example includes the first transistor portion 42, the second diode portion 48 connected in series with the first transistor portion 42, and the test terminal 28 connected between the first transistor portion 42 and the second diode portion 48. The semiconductor device 100 of the present example makes up the upper arm circuit 10 or the lower arm circuit 12 in FIG. 11. The semiconductor device 100 of the present example includes the test terminal 28, so that the characteristic test can be performed on each element even after the semiconductor device 100 was made.

FIG. 13C shows an insulating plate 20 of a variation of the semiconductor device 100. The semiconductor device 100 of the present example is made such that the first transistor portion 42 included in the upper arm circuit 10 and the second diode portion 48 included in the lower arm circuit 12 are removed from the semiconductor device 100 according to the example of FIG. 10B. The semiconductor device 100 of the present example makes up the upper arm circuit 10 or the lower arm circuit 12 of FIG. 3.

The semiconductor device 100 includes a test terminal 28 connected between the second transistor portion 44 and the first diode portion 46. The output terminal 22 in the semiconductor device 100 according to the example of FIG. 10B is the test terminal 28 in the present example. Also, the positive electrode terminal 24 according to the example of FIG. 10B is a positive electrode side terminal 25 in the present example, and the negative electrode terminal 26 according to the example of FIG. 10B is a negative electrode side terminal 27 in the present example. In the semiconductor device 100 of the present example, since the first transistor portion 42 included in the upper arm circuit 10 is removed from the semiconductor device 100 according to the example of FIG. 10B and the output terminal 22 of the example of FIG. 10B is the test terminal 28, the upper arm side gate connecting portion 52-1 and the upper arm side emitter connecting portion 62-1, and the gate terminal 50 and the emitter terminal 60 connected thereto may not be used.

Since the role of each terminal is changed, the semiconductor device 100 of the present example can be made without changing the appearance of the package from that of the semiconductor device 100 according to the example of FIG. 10B. This makes it possible to improve the compatibility between the semiconductor devices.

FIG. 13D shows a circuit configuration of the variation of the semiconductor device 100. The semiconductor device 100 of the present example includes the second transistor portion 44, the first diode portion 46 connected in series with the second transistor portion 44, and the test terminal 28 connected between the second transistor portion 44 and the first diode portion 46. The semiconductor device 100 of the present example makes up the upper arm circuit 10 or the lower arm circuit 12 in FIG. 3. The semiconductor device 100 of the present example includes the test terminal 28, so that the characteristic test can be performed on each element even after the semiconductor device 100 was made.

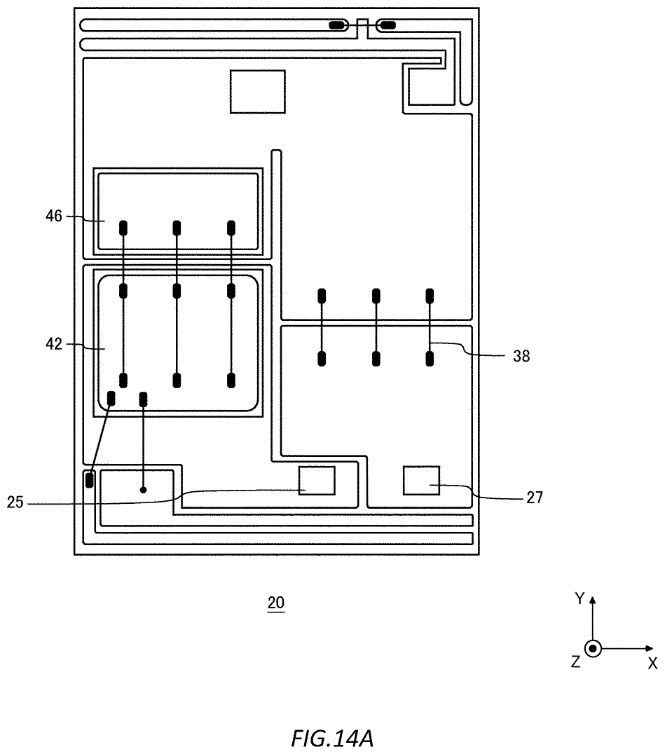

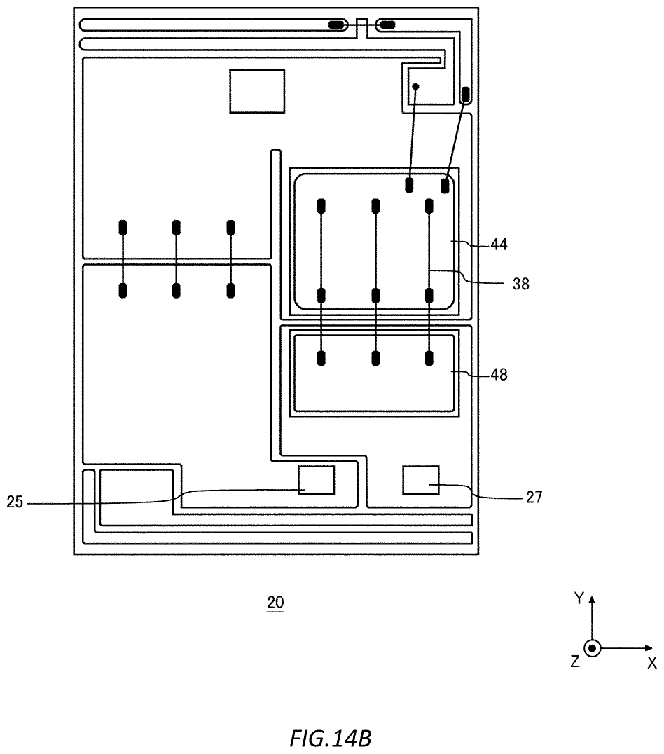

FIG. 14A shows an insulating plate 20 of a variation of the semiconductor device 100. The semiconductor device 100 of the present example is made such that the second transistor portion 44 and the second diode portion 48 included in the lower arm circuit 12 are removed from the semiconductor device 100 according to the example of FIG. 10B, and makes up the upper arm circuit 10 or the lower arm circuit 12 of FIG. 11. In the semiconductor device 100 of the present example, since the second transistor portion 44 included in the lower arm circuit 12 is removed from the semiconductor device 100 according to the example of FIG. 10B, the lower arm side gate connecting portion 52-2 and the lower arm side emitter connecting portion 62-2, and the gate terminal 50 and the emitter terminal 60 connected thereto may not be used. Also in the present example, the semiconductor device 100 can be made without changing the appearance of the package, and the compatibility between the semiconductor devices can be improved.

FIG. 14B shows an insulating plate 20 of a variation of the semiconductor device 100. The semiconductor device 100 of the present example is made such that the first transistor portion 42 and the first diode portion 46 included in the upper arm circuit 10 are removed from the semiconductor device 100 according to the example of FIG. 10B, and makes up the upper arm circuit 10 or the lower arm circuit 12 of FIG. 3. In the semiconductor device 100 of the present example, since the first transistor portion 42 included in the upper arm circuit 10 is removed from the semiconductor device 100 according to the example of FIG. 14B, the upper arm side gate connecting portion 52-1 and the upper arm side emitter connecting portion 62-1, and the gate terminal 50 and the emitter terminal 60 connected thereto may not be used. Also in the present example, the semiconductor device 100 can be made without changing the appearance of the package, and the compatibility between the semiconductor devices can be improved.

While the present invention has been described above by way of the embodiments, the technical scope of the present invention is not limited to the scope described in the above-described embodiments. It is apparent to persons skilled in the art that various changes or improvements can be made to the above-described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### (Item 1)

A semiconductor device including an upper arm circuit and a lower arm circuit and having a positive electrode terminal, a negative electrode terminal, and an output terminal, including
an insulating plate;
a first wiring pattern provided on the insulating plate; and
a second wiring pattern provided on the insulating plate and spaced apart from the first wiring pattern,
in which the upper arm circuit has
a circuit in which
the positive electrode terminal,
a first diode portion provided on the first wiring pattern,
a first transistor portion connected in series with the first diode portion and provided on the first wiring pattern, and
the output terminal
are connected and arranged in this order, and
the lower arm circuit has
a second transistor portion provided on the second wiring pattern, and
a second diode portion provided on the second wiring pattern.

### (Item 2)

The semiconductor device according to item 1, in which
the lower arm circuit has a circuit in which the output terminal, the second diode portion, the second transistor portion, and the negative electrode terminal are connected and arranged in this order.

### (Item 3)

The semiconductor device according to item 1, in which
the first transistor portion is provided such that a collector electrode contacts the first wiring pattern, and
the first diode portion is provided such that a cathode electrode contacts the first wiring pattern.

### (Item 4)

The semiconductor device according to item 1, in which
the second transistor portion is provided such that a collector electrode contacts the second wiring pattern, and
the second diode portion is provided such that a cathode electrode contacts the second wiring pattern.

### (Item 5)

The semiconductor device according to item 1, in which
an emitter electrode of the first transistor portion is connected to the output terminal via a wire member.

### (Item 6)

The semiconductor device according to item 1, in which
an anode electrode of the first diode portion is connected to the positive electrode terminal via a wire member.

### (Item 7)

The semiconductor device according to item 1, in which
an anode electrode of the second diode portion is connected to the output terminal via a wire member.

### (Item 8)

The semiconductor device according to item 1, in which
an emitter electrode of the second transistor portion is connected to the negative electrode terminal via a wire member.

### (Item 9)

The semiconductor device according to item 1, in which
the output terminal is provided on a positive side in a predetermined first direction with respect to the positive electrode terminal and the negative electrode terminal.

### (Item 10)

The semiconductor device according to item 9, in which
the first wiring pattern and the second wiring pattern are arrayed in a predetermined second direction different from the first direction,
the first wiring pattern is provided on a positive side in the second direction with respect to the second wiring pattern, and
the positive electrode terminal is provided on a positive side in the second direction with respect to the negative electrode terminal.

### (Item 11)

The semiconductor device according to item 10, in which
the output terminal is provided on a positive side in the first direction with respect to the first wiring pattern and the second wiring pattern.

### (Item 12)

The semiconductor device according to item 10, in which
the negative electrode terminal is provided on a negative side in the first direction with respect to the first wiring pattern and the second wiring pattern.

### (Item 13)

The semiconductor device according to item 10, in which
the positive electrode terminal is provided on a negative side in the first direction with respect to the first wiring pattern and the second wiring pattern.

### (Item 14)

A semiconductor device including
a positive electrode terminal and a negative electrode terminal forming a path through which a main current flows upon operation of the semiconductor device;
a transistor portion provided between the positive electrode terminal and the negative electrode terminal;
a diode portion connected in series with the transistor portion between the positive electrode terminal and the negative electrode terminal; and
an external test terminal connected between the transistor portion and the diode portion.

### (Item 15)

A semiconductor device including
a transistor portion provided on a first semiconductor chip;
a diode portion connected in series with the transistor portion and provided on a second semiconductor chip different from the first semiconductor chip; and
an external test terminal connected between the transistor portion and the diode portion.

### (Item 16)

A semiconductor device having an upper arm circuit and a lower arm circuit, including
an insulating plate;
a positive electrode terminal and a negative electrode terminal provided in a first region on the insulating plate; and
an output terminal provided in a second region different from the first region on the insulating plate,
in which the upper arm circuit has
a first diode portion provided in a third region between the first region and the second region on the insulating plate, and
a first transistor portion connected in series with the first diode portion in the third region, and
the lower arm circuit has
a second diode portion provided in the third region, and
a second transistor portion connected in series with the second diode portion in the third region.

### (Item 17)

The semiconductor device according to item 16, in which
the first region is provided adjacent to a first end side of the insulating plate, and
the second region is provided adjacent to a second end side of the insulating plate opposing the first end side.

### (Item 18)

The semiconductor device according to item 16 or 17, in which
the positive electrode terminal, the first transistor portion, the first diode portion, and the output terminal are electrically connected in this order, and
the output terminal, the second transistor portion, the second diode portion, and the negative electrode terminal are electrically connected in this order.

### (Item 19)

The semiconductor device according to item 16 or 17, in which
the second region is provided on a positive side in a predetermined first direction with respect to the first region,
the first transistor portion and the first diode portion, and the second transistor portion and the second diode portion are arrayed in a predetermined second direction different from the first direction, and
the first transistor portion and the first diode portion are provided on a negative side in the second direction with respect to the second transistor portion and the second diode portion.

### (Item 20)

The semiconductor device according to item 19, in which
the positive electrode terminal is provided on a negative side in the second direction with respect to the negative electrode terminal.

### (Item 21)

The semiconductor device according to item 19, in which
the first transistor portion is provided on a negative side in the first direction with respect to the first diode portion.

### (Item 22)

The semiconductor device according to item 19, in which
the second transistor portion is provided on a positive side in the first direction with respect to the second diode portion.

### (Item 23)

The semiconductor device according to item 19, in which
the first transistor portion is provided on a positive side in the first direction with respect to the first diode portion.

### (Item 24)

The semiconductor device according to item 19, in which
the second transistor portion is provided on a negative side in the first direction with respect to the second diode portion.

### (Item 25)

The semiconductor device according to item 16 or 17, in which
the positive electrode terminal, the first diode portion, the first transistor portion, and the output terminal are electrically connected in this order, and
the output terminal, the second diode portion, the second transistor portion, and the negative electrode terminal are electrically connected in this order.

### (Item 26)

The semiconductor device according to item 16 or 17, in which
the second region is provided on a positive side in a predetermined first direction with respect to the first region,
the first transistor portion and the first diode portion, and the second transistor portion and the second diode portion are arrayed in a predetermined second direction different from the first direction, and
the first transistor portion and the first diode portion are provided on a positive side in the second direction with respect to the second transistor portion and the second diode portion.

### (Item 27)

The semiconductor device according to item 26, in which
the positive electrode terminal is provided on a positive side in the second direction with respect to the negative electrode terminal.

### (Item 28)

The semiconductor device according to item 26, in which
the first transistor portion is provided on a positive side in the first direction with respect to the first diode portion.

### (Item 29)

The semiconductor device according to item 26, in which
the second transistor portion is provided on a negative side in the first direction with respect to the second diode portion.

### (Item 30)

A semiconductor device including
a transistor portion;
a diode portion connected in series with the transistor portion; and
an external test terminal connected between the transistor portion and the diode portion,
in which the external test terminal is connected to a connection point of an emitter or a source of the transistor portion and an anode of the diode portion.

### (Item 31)

A semiconductor device including
a transistor portion;
a diode portion connected in series with the transistor portion; and
an external test terminal connected between the transistor portion and the diode portion,
in which the external test terminal is connected to a connection point of a collector or a drain of the transistor portion and a cathode of the diode portion.

### EXPLANATION OF REFERENCES

10: Upper Arm Circuit; 12: Lower Arm Circuit, 14: Power Source; 16: External Load; 20: Insulating Plate; 22: Output Terminal; 24: Positive Electrode Terminal; 25: Positive Electrode Side Terminal; 26: Negative Electrode Terminal; 27: Negative Electrode Side Terminal; 28: Test Terminal; 30: Lead Frame; 32: Leg Portion; 34: Flat Plate Portion; 38: Wire Member; 40: First Wiring Pattern; 41: Second Wiring Pattern; 42: First Transistor Portion; 43: Third Wiring Pattern; 44: Second Transistor Portion; 46: First Diode Portion; 48: Second Diode Portion; 50: Gate Terminal; 52: Gate Connecting Portion; 60: Emitter Terminal; 62: Emitter Connecting Portion; 66: Auxiliary Collector Terminal; 68: Auxiliary Collector Connecting Portion; 70: External Output Terminal; 72: External Positive Electrode Terminal; 74: External Negative Electrode Terminal; 76: External Test Terminal; 80 Temperature Sense Terminal; 82: Temperature Sense Connecting Portion; 84: Temperature Sense Portion; 100: Semiconductor Device; 110: Casing Portion; 112: Cutout; 114: Terminal Arrangement Surface; 116: Protrusion; 120: Base Portion; 201: First End Side; 202: Second End Side; 210: First Region; 220: Second Region; 230: Third Region.

What is claimed is:

1. A semiconductor device including an upper arm circuit and a lower arm circuit and having a positive electrode terminal, a negative electrode terminal, and an output terminal, comprising:
an insulating plate;
a first wiring pattern provided on the insulating plate; and
a second wiring pattern provided on the insulating plate and spaced apart from the first wiring pattern,
wherein the upper arm circuit has
a circuit in which
the positive electrode terminal,
a first diode portion provided on the first wiring pattern,
a first transistor portion connected in series with the first diode portion and provided on the first wiring pattern, and
the output terminal
are connected and arranged in this order, and
the lower arm circuit has
a second transistor portion provided on the second wiring pattern, and
a second diode portion provided on the second wiring pattern.

2. The semiconductor device according to claim 1, wherein
the lower arm circuit has a circuit in which the output terminal, the second diode portion, the second transistor portion, and the negative electrode terminal are connected and arranged in this order.

3. The semiconductor device according to claim 1, wherein
the first transistor portion is provided such that a collector electrode contacts the first wiring pattern, and
the first diode portion is provided such that a cathode electrode contacts the first wiring pattern.

4. The semiconductor device according to claim 1, wherein
the second transistor portion is provided such that a collector electrode contacts the second wiring pattern, and
the second diode portion is provided such that a cathode electrode contacts the second wiring pattern.

5. The semiconductor device according to claim 1, wherein
an emitter electrode of the first transistor portion is connected to the output terminal via a wire member, and
an anode electrode of the first diode portion is connected to the positive electrode terminal via a wire member.

6. The semiconductor device according to claim 1, wherein
an anode electrode of the second diode portion is connected to the output terminal via a wire member, and
an emitter electrode of the second transistor portion is connected to the negative electrode terminal via a wire member.

7. The semiconductor device according to claim 1, wherein
the output terminal is provided on a positive side in a predetermined first direction with respect to the positive electrode terminal and the negative electrode terminal,
the first wiring pattern and the second wiring pattern are arrayed in a predetermined second direction different from the first direction,
the first wiring pattern is provided on a positive side in the second direction with respect to the second wiring pattern, and
the positive electrode terminal is provided on a positive side in the second direction with respect to the negative electrode terminal.

8. The semiconductor device according to claim 7, wherein
the output terminal is provided on a positive side in the first direction with respect to the first wiring pattern and the second wiring pattern.

9. The semiconductor device according to claim 7, wherein
the negative electrode terminal is provided on a negative side in the first direction with respect to the first wiring pattern and the second wiring pattern.

10. The semiconductor device according to claim 7, wherein
the positive electrode terminal is provided on a negative side in the first direction with respect to the first wiring pattern and the second wiring pattern.

11. A semiconductor device including an upper arm circuit and a lower arm circuit, comprising:
an insulating plate;
a positive electrode terminal and a negative electrode terminal provided in a first region on the insulating plate; and
an output terminal provided in a second region different from the first region on the insulating plate,
wherein the upper arm circuit has
a first diode portion provided in a third region between the first region and the second region on the insulating plate, and
a first transistor portion connected in series with the first diode portion in the third region, and
the lower arm circuit has
a second diode portion provided in the third region, and
a second transistor portion connected in series with the second diode portion in the third region.

12. The semiconductor device according to claim 11, wherein
the first region is provided adjacent to a first end side of the insulating plate, and
the second region is provided adjacent to a second end side of the insulating plate opposing the first end side.

13. The semiconductor device according to claim 11, wherein
the positive electrode terminal, the first transistor portion, the first diode portion, and the output terminal are electrically connected in this order, and
the output terminal, the second transistor portion, the second diode portion, and the negative electrode terminal are electrically connected in this order.

14. The semiconductor device according to claim 11, wherein
the second region is provided on a positive side in a predetermined first direction with respect to the first region,
the first transistor portion and the first diode portion, and the second transistor portion and the second diode portion are arrayed in a predetermined second direction different from the first direction,
the first transistor portion and the first diode portion are provided on a negative side in the second direction with respect to the second transistor portion and the second diode portion, and
the positive electrode terminal is provided on a negative side in the second direction with respect to the negative electrode terminal.

15. The semiconductor device according to claim 14, wherein
the first transistor portion is provided on a negative side in the first direction with respect to the first diode portion, and
the second transistor portion is provided on a positive side in the first direction with respect to the second diode portion.

16. The semiconductor device according to claim 14, wherein
the first transistor portion is provided on a positive side in the first direction with respect to the first diode portion, and
the second transistor portion is provided on a negative side in the first direction with respect to the second diode portion.

17. The semiconductor device according to claim 11, wherein
the positive electrode terminal, the first diode portion, the first transistor portion, and the output terminal are electrically connected in this order, and
the output terminal, the second diode portion, the second transistor portion, and the negative electrode terminal are electrically connected in this order.

18. The semiconductor device according to claim 11, wherein
the second region is provided on a positive side in a predetermined first direction with respect to the first region,
the first transistor portion and the first diode portion, and the second transistor portion and the second diode portion are arrayed in a predetermined second direction different from the first direction,
the first transistor portion and the first diode portion are provided on a positive side in the second direction with respect to the second transistor portion and the second diode portion, and
the positive electrode terminal is provided on a positive side in the second direction with respect to the negative electrode terminal.

19. The semiconductor device according to claim 18, wherein
the first transistor portion is provided on a positive side in the first direction with respect to the first diode portion.

20. The semiconductor device according to claim 18, wherein
the second transistor portion is provided on a negative side in the first direction with respect to the second diode portion.
